(19) United States
(12) Patent Application Publication
(10) Pub. No.: US 2021/0284893 A1
(43) Pub. Date: Sep. 16, 2021

(54) METHOD FOR PREPARING EXPANDED HEXAGONAL BORON NITRIDE BY TEMPLATING

(71) Applicants: ROGERS CORPORATION, Chandler, AZ (US); TSINGHUA UNIVERSITY, Beijing (CN)

(72) Inventors: Yang Zhong, Suzhou (CN); Lei Liu, Suzhou (CN); Jing Jiang, Suzhou (CN); Li Zhang, Glen Mills (PA); Kexin Chen, Beijing (CN); Zhaobo Tian, Beijing (CN); Yiyao Ge, Beijing (CN)

(21) Appl. No.: 16/330,442

(22) PCT Filed: Sep. 13, 2017
(86) PCT No.: PCT/US2017/051267

§ 371 Date: Mar. 5, 2019

(30) Foreign Application Priority Data
Sep. 13, 2016 (CN) 201610822221.6

(51) Int. Cl. C09K 5/14; C01B 21/064; C08K 3/38; C08J 9/00; F28D 20/02

(52) U.S. Cl. CPC C09K 5/14; C08J 2387/00; C08K 3/38; C08J 9/0066; F28D 20/023; C01P 2002/72; C01P 2004/03; C01P 2006/12; C01P 2006/80; C01P 2006/32; C01P 2002/76; C08K 2003/385; C08K 2201/001; C08K 2201/006; C01B 21/0645

(57) ABSTRACT

In an embodiment, a method for preparing expanded hexagonal boron nitride comprises mixing a boron compound and a carbon template in an organic solvent; removing the organic solvent to provide a dried mixture of the boron compound and the carbon template; exposing the dried mixture to a nitrogen-containing gas under conditions effective to provide a crude product comprising hexagonal boron nitride; removing the carbon template from the crude product to provide the expanded hexagonal boron nitride.

### CROSS-REFERENCE TO RELATED APPLICATION

This application claims the benefit of Chinese Patent Application Serial No. 201610822221.6 filed Sep. 13, 2016. The related application is incorporated herein in its entirety by reference.

### BACKGROUND

Expanded graphite is a loose, porous substance that is obtained by subjecting natural graphite scales to high-temperature expansion. As well as having the excellent properties of natural graphite itself, expanded graphite also has properties that natural graphite lacks, such as softness, compression resilience, adsorption, harmony with the ecological environment, biocompatibility, and radiation resistance. Because of these beneficial properties, expanded graphite has gradually found many important applications in fields such as high-energy battery materials, sealing materials, biomedicine, phase-change heat storage materials, and environmental protection. However, graphite is a good conductor of electricity, so cannot be used in many applications which require insulation, such as microelectronic encapsulation.

The crystal structure of hexagonal boron nitride is similar to graphite, both having a hexagonal crystal system and a laminar structure with multiple layers being joined by means of molecular bonds. Hexagonal boron nitride has a very good lubricating effect and is often referred to as “white graphite.” Hexagonal boron nitride not only has a structure and properties similar to those of graphite material, but also has some excellent properties that graphite lacks, such as electrical insulation, corrosion resistance and good high-temperature performance. If expanded hexagonal boron nitride with structural features similar to those of expanded graphite could be prepared, it would have broad application prospects in fields such as electronics, machinery, environmental protection, and atomic energy. However, the molecular bonds joining layers of hexagonal boron nitride are far stronger than the molecular bonds joining layers of graphite, making it extremely difficult to open up the molecular bonds joining layers of hexagonal boron nitride by employing the methods commonly used to prepare expanded graphite, namely intercalation, washing in water, drying, and high-temperature expansion. Therefore, at the present time there appear to be no expanded hexagonal boron nitride products and no reports pertaining to the preparation of expanded hexagonal boron nitride.

Accordingly, a method for successfully preparing a hexagonal expanded boron nitride exists.

### BRIEF SUMMARY

Disclosed herein is a method of preparing a hexagonal expanded boron nitride and the hexagonal expanded boron nitride made therefrom.

In an embodiment, a method for preparing expanded hexagonal boron nitride comprises mixing a boron compound and a carbon template in an organic solvent; removing the organic solvent to provide a dried mixture of the boron compound and the carbon template; exposing the dried mixture to a nitrogen-containing gas under conditions effective to provide a crude product comprising hexagonal boron nitride; removing the carbon template from the crude product to provide the expanded hexagonal boron nitride.

Also disclosed herein is an expanded hexagonal boron nitride.

Further disclosed is a composite material comprising the expanded hexagonal boron nitride and a polymer.

Further disclosed is a thermal management assembly comprising expanded hexagonal boron nitride.

Further still is disclosed an article comprising an expanded hexagonal boron nitride.

The above described and other features are exemplified by the following figures and detailed description.

### BRIEF DESCRIPTION OF THE DRAWINGS

The following Figures are exemplary embodiments, which are provided to illustrate the method of making the hexagonal expanded boron nitride and the hexagonal expanded boron nitride made therefrom. The figures are illustrative of the examples, which are not intended to limit devices made in accordance with the disclosure to the materials, conditions, or process parameters set forth herein.

FIG. 1 is a graphical illustration of the X-ray diffraction spectrum for the expanded hexagonal boron nitride synthesized in Example 1;

FIG. 2 is a scanning electron microscope (SEM) image of the microstructure of the expanded hexagonal boron nitride synthesized in Example 1;

FIG. 3 is a graphical illustration of the X-ray diffraction spectrum for the expanded hexagonal boron nitride synthesized in Example 2;

FIG. 4 is a graphical illustration of the X-ray diffraction spectrum for the expanded hexagonal boron nitride synthesized in Example 4;

FIG. 5 is a scanning electron microscope image of the morphology of the expanded hexagonal boron nitride synthesized in Example 4; and

FIG. 6 is a scanning electron microscope image of the morphology of the expanded hexagonal boron nitride synthesized in Example 4.

### DETAILED DESCRIPTION

It was surprisingly discovered that a hexagonal expanded boron nitride could be prepared by templating the hexagonal expanded boron nitride off of a carbon template. Specifically, the method comprises mixing a boron compound and a carbon template in an organic solvent; removing the organic solvent to provide a dried mixture of the boron compound and the carbon template; exposing the dried mixture to a nitrogen-containing gas under conditions effective to provide a crude product comprising hexagonal boron nitride; and removing the carbon template from the crude product to provide the expanded hexagonal boron nitride. Due to the use of the carbon template as a direct template for the hexagonal structure of the boron nitride, the present method can beneficially provide the boron nitride morphology that copies of the morphology of the carbon template, allowing for different morphologies to be formed, for example, particulate and nanosheet morphologies.

The method has the benefit in that it can be used to manufacture large quantities of expanded hexagonal boron nitride having a high purity, for example, of 95 to 100 weight percent (wt %), or 99 to 100 wt % based on a total weight of the expanded hexagonal boron nitride. The method can be environmentally friendly as it can use environmentally friendly boron and carbon sources and, as the carbon source of graphite is easy to degrade, acid washing and water washing steps can be avoided.

The method comprises mixing a boron compound and a carbon template in an organic solvent. The boron compound can comprise any boron-containing compound that produces boron nitride under the carbothermal reduction and nitridation conditions described below. Oxygen-containing boron compounds can be used, including various salts and hydrates. The oxygen-containing boron compound can be an amine pentaborate, a borate ester, borax (Na₂B₄O₇.10H₂O or Na₂[B₄O₅(OH)₄]. 8H₂O), boric acid (H₃BO₃) or a salt thereof, pyroboric acid (B₄H₂O₇) or a salt thereof, tetraboric acid (H₂B₄O₇) or a salt thereof, boron oxide (B₂O₃), or a combination comprising one or more of the foregoing. The amine pentaborate includes any amine salt e.g., an amine salt of the formula B₅O₈⁻NR₄⁺ or B₅O₆(OH)₄⁻NR₄⁺ wherein each R can the same or different, and is hydrogen or an organic ligand, for example a C₁₋₈ alkyl group or a C₄₋₈ cycloalkyl group. Ammonium pentaborate (B₅O₈⁻NR₄⁻′) can be used. The borate ester can be any ester of boric acid, e.g., an ester of the formula B(OR)₃ wherein each R can the same or different, and is an organic ligand, for example a C₁₋₁₂ alkyl group organic ligand, for example a C₁₋₁₂ alkyl group. The corresponding salts of the various acids can have any counterion, e.g., ammonium, phosphonium, an alkali metal, an alkaline earth metal, or a combination comprising one or more of the foregoing. The boron compound can comprise boric acid, pyroboric acid, boron oxide, or a combination comprising one or more of the foregoing. The boron compound can comprise boron oxide.

The carbon template can comprise an expanded graphite (also known as expanded carbon, expandable graphite, or intercalated graphite), carbon fibers, a graphite film, graphene, an activated carbon, carbon nanotubes, or a combination comprising at least one of the foregoing. The carbon template can comprise the expanded graphite and can be referred to as a graphite template. Expanded graphite can be prepared by inserting an intercalant material between respective graphene layers and heating the intercalant material to force the respective graphene layers to separate from each other. The resultant expanded graphite can have an accordion-like morphology. The carbon template can comprise a surface treated carbon template to increase the ability of the boron compound to absorb onto the carbon template. For example, the carbon template can be surface treated to comprise one or both of hydroxyl and carboxyl functional groups.

The organic solvent can comprise a C₁₋₆ alkanol (for example, ethanol, methanol, propanol, butanol, pentanol, and hexanol), a polyol (for example, glycerin, pentaerythritol, ethylene glycol, and sucrose), a polyether (for example, polyethylene glycol and polypropylene glycol), or a combination comprising one or more of the foregoing. The organic solvent can comprise ethanol, methanol, glycerin, polyethylene glycol, or a combination comprising one or more of the foregoing.

The mixture can comprise 5 to 200 milliliters (mL), or 5 to 25 mL, or 5 to 15 mL, or 25 to 200 mL of the organic solvent per 1 gram (g) of the total of the boron compound and the carbon template.

The mixture can further comprise a dispersant to improve dispersion of the boron compound and the carbon template. The type of dispersant can depend on the type of boron compound and the type of carbon template. The dispersant can be a surfactant. The surfactant can be anionic, nonionic, cationic, or zwitterionic. Preferably the surfactant is anionic.

Among the anionic surfactants that can be used are the alkali metal, alkaline earth metal, ammonium and amine salts of organic sulfuric reaction products having in their molecular structure a C₈₋₃₆, or C₈₋₂₂, alkyl or acyl group and a sulfonic acid or sulfuric acid ester group. In an embodiment the dispersant comprises sodium dodecyl sulfate, sodium lauryl sulfate, sodium laureth sulfate, sodium dioctyl sulfosuccinate, sodium dihexyl sulfosuccinate, perfluorooctane sulfonate, perfluorooctanoic acid, or sodium dodecylbenzenesulfonate. In an embodiment the dispersant is sodium dodecyl sulfate.

Nonionic surfactants can be used and can include a C₈₋₂₂ aliphatic alcohol ethoxylate having about 1 to about 25 moles of ethylene oxide and having have a narrow homolog distribution of the ethylene oxide (“narrow range ethoxylates”) or a broad homolog distribution of the ethylene oxide (“broad range ethoxylates”); and preferably C₁₀₋₂₀ aliphatic alcohol ethoxylates having about 2 to about 18 moles of ethylene oxide. Examples of commercially available nonionic surfactants of this type are TERGITOL 15-S-9 (a condensation product of C₁₁₋₁₅ linear secondary alcohol with 9 moles ethylene oxide), TERGITOL 24-L-NMW (a condensation product of C₁₂₋₁₄ linear primary alcohol with 6 moles of ethylene oxide) with a narrow molecular weight distribution, from Dow. Other nonionic surfactants that can be used include polyethylene, polypropylene, and polybutylene oxide condensates of C₆₋₁₂ alkyl phenols, for example compounds having 4 to 25 moles of ethylene oxide per mole of C₆₋₁₂ alkylphenol, preferably 5 to 18 moles of ethylene oxide per mole of C₆₋₁₂ alkylphenol. Commercially available surfactants of this type include Igepal CO-630, TRITON X-45, X-114, X-100 and X102, TERGITOL TMN-10, TERGITOL TMN-100X, and TERGITOL TMN-6 (all polyethoxylated 2,6,8-trimethyl-nonylphenols or mixtures thereof) from Dow.

The mixture can comprise 0.01 to 10 wt % or 0.1 to 5 wt % of the dispersant, based on the total weight of the boron compound and the carbon template.

The mixture can have a molar ratio of carbon template to the boron compound of 1:0.2 to 1:2.

The mixing can occur at a temperature of 0 to 60 degrees Celsius (° C.), or 10 to 50° C., or 15 to 35° C. The mixing can occur for 0.5 to 10 hours, or 0.5 to 5 hours, or 0.5 to 1.5 hours, or 2 hours to 10 hours, or 5 to 9 hours. The mixing time can have an effect on the resultant morphology of the expanded hexagonal boron nitride. For example, and without being bound by theory, if the carbon template in particulate form is vigorously mixed and/or is mixed for an increased mixing time (for example, of greater than or equal to 2 hours), then the mixing can result in disruption of the graphite particles to form graphite nanosheets. Therefore, the expanded hexagonal boron nitride templated from the graphite nanosheets results in the formation of expanded hexagonal boron nitride nanosheets. If the mixing is gentle and/or if the time is reduced (for example, of less than 2 hours), then the particulate graphite morphology can remain relatively undisrupted and the resultant expanded hexagonal boron nitride will be particulate.

The mixing can comprise wet ball mixing. The mixing can comprise stirring, for example, with a magnetic stir bar. The mixing can comprise ultrasonically vibrating the mixture. The mixture can be ultrasonically vibrated for 1 to 5 hours, or 1 to 3 hours. Using a method such as stirring for greater than or equal to 2 hours, ultrasonically vibrating during mixing, and wet ball mixing can disrupt the particulate morphology of the particulate graphite, increasing the surface area of the particulate graphite available for templating and can also result in the formation of graphite nanosheets.

After the mixing, the organic solvent can be removed to form a dried mixture of the carbon template and the boron compound. The dried mixture can be formed by one or more heating the mixture, applying a vacuum pressure to the mixture, and freeze-drying the mixture. Freeze-drying the mixture can have the benefit of reducing the amount of boron compound separated from the carbon template during the removal of the organic solvent. The dry mixture can comprise less than or equal to 1 mL, or 0 to 0.1 mL of the organic solvent per 1 g of the total of the boron compound and the carbon template.

The dried mixture is then exposed to conditions effective to form the hexagonal boron nitride in an expanded form. Without being bound by theory, it is believed that the effective conditions are a carbothermal reduction process. Starting with boron oxide, such a carbothermal reduction and nitridation reaction can proceed in accordance with the following equation:

$${B}_{2} {O}_{3} + 3 C + {N}_{2} \to 2 B N + 3 C O$$

Again without being bound by theory, it is believed that the boron nitride is formed on the carbon template to provide a physically expanded form.

The carbothermal reduction and nitridation reaction (also referred to herein as the reaction for ease or reference) can be performed on the dried mixture by flowing a nitrogen gas through the dried mixture for 1 to 10 hours to provide a crude product. The reaction time can be 1 to 15 hours, or 1 to 10 hours, or 3 to 10 hours, or 5 to 15 hours. A flow rate of the nitrogen gas can be 40 to 1,000 milliliters per minute (mL/min), or 60 to 200 mL/min during the exposing.

The reaction can be performed in an oxygen free environment. For example, the oxygen free environment can comprise less than or equal to 100 parts per million (ppm), or less than or equal to 10 ppm by volume of oxygen. The reaction can occur in a reaction chamber, for example, in a crucible (for example, a graphite crucible or a clay crucible). The dried mixture can be spread out to form a thin layer in the reaction chamber. The thin layer can have a layer thickness of less than or equal to 1 millimeters (mm), or 0.1 to 0.5 mm. The reaction chamber can be located in a furnace, for example, in a tubular furnace during the exposing.

The exposing can occur at an increased temperature, for example, at a temperature of 400 to 1,600° C., or 600 to 1,500° C. The use of a suitable heating system can prevent the boron compound from undergoing reactions other than the carbothermal reduction and nitridation reaction, thereby avoiding a reduced output of expanded hexagonal boron nitride. The increased temperature can be achieved in one or more, or two or more, or three or more heating stages. The heating stages can increase the temperature at a rate of 1 to 15 degree Celsius per minute (° C./min), or 5 to 12° C./min. If a single heating stage is used, the heating rate can be less than or equal to 5° C./min, or less than or equal to 1° C./min. After each heating stage, the temperature can be maintained for an amount of time, for example, of 1 to 5 hours, or 1 to 3 hours before the subsequent heating stage is initiated.

An exemplary heating can comprise heating the dry mixture to a first temperature of 100 to 500° C. at a rate of 3 to 10° C./min; maintaining the first temperature for 0.5 to 3 hours; heating to a second temperature of 700 to 1,100° C. at a rate of 3 to 10° C./min; maintaining the second temperature for 0.5 to 3 hours; heating to a third temperature of 1,200 to 1,700° C. at a rate of 3 to 10° C./min; and maintaining the third temperature for 0.5 to 3 hours.

After the reaction, the carbon template can be removed from the crude product to provide the expanded hexagonal boron nitride, for example, by heating. The heating to remove the carbon template can occur in oxygen or air. The heating to remove the carbon template can comprise reacting with oxygen in the boron compound if present, for example, if the boron compound comprises boron oxide. The heating to remove the carbon template can occur at a temperature of 500 to 1,000° C., or 600 to 900° C., or 700 to 800° C. The heating to remove the carbon template can occur for a time period of 1 to 15 hours, or 3 to 10 hours, or 3 to 8 hours.

The expanded hexagonal boron nitride can have a specific surface area of 20 to 100 meters squared per gram (m²/g), or 70 to 100 m²/g, or 20 to 90 m²/g. The expanded hexagonal boron nitride can have an expanded specific volume of 100 to 200 milliliters per gram (mL/g), or 140 to 200 mL/g, or 90 to 200 mL/g. These values can be determined using the Brunauer-Emmett-Teller (BET) method.

The expanded hexagonal boron nitride can have a thermal conductivity, according to ASTM E1225-13, of 1 to 2,000 watts per meter-Kelvin (W/m·K) or more, or 1 to 2,000 W/m·K, or 10 to 1,800 W/m·K, or 100 to 1,600 W/m·K, or 1,500 to 2,000 W/m·K. The expanded hexagonal boron nitride can also have an electrical resistivity of 5 to 15 ohm-centimeters (Ω-cm) at room temperature (for example, at 25° C.), or 8 to 12 Ω-cm, a dielectric constant of 3 to 4, for example 3.01 to 3.36 at room temperature at 5.75×10⁹ hertz (Hz), and a loss tangent of 0.0001 to 0.001, or 0.0003 to 0.0008 at room temperature at 5.75×10⁹ Hz, or 0.0003 to 0.0008.

The present method can result in an efficient, low-cost preparation of expanded hexagonal boron nitride to open up a new shortcut for further improvement of the quality and output of two-dimensional hexagonal expanded boron nitride nanosheets or three-dimensional expanded hexagonal boron nitride particles that can lay a strong foundation for the manufacture of an isotropic, insulating composite material with high thermal conductivity. The composite material can comprise the expanded hexagonal boron nitride and a polymer. The polymer can comprise a thermoset polymer or a thermoplastic polymer. The polymer can be a foam.

Thermoset polymers are derived from thermosetting monomers or prepolymers (resins) that can irreversibly harden and become insoluble with polymerization or cure, which can be induced by heat or exposure to radiation (e.g., ultraviolet light, visible light, infrared light, or electron beam (e-beam) radiation). Thermoset polymers include alkyds, bismaleimide polymers, bismaleimide triazine polymers, cyanate ester polymers, benzocyclobutene polymers, benzoxazine polymers, diallyl phthalate polymers, epoxies, hydroxymethylfuran polymers, melamine-formaldehyde polymers, phenolics (including phenol-formaldehyde polymers such as novolacs and resoles), benzoxazines, polydienes such as polybutadienes (including homopolymers and copolymers thereof, e.g. poly(butadiene-isoprene)), polyisocyanates, polyureas, polyurethanes, triallyl cyanurate polymers, triallyl isocyanurate polymers, certain silicone polymers, and polymerizable prepolymers (e.g., prepolymers having ethylenic unsaturation, such as unsaturated polyesters, polyimides), or the like. The prepolymers can be polymerized, copolymerized, or crosslinked, e.g., with a reactive monomer such as styrene, alpha-methylstyrene, vinyltoluene, chlorostyrene, acrylic acid, (meth)acrylic acid, a (C₁₋₆ alkyl)acrylate, a (C₁₋₆ alkyl) methacrylate, acrylonitrile, vinyl acetate, allyl acetate, triallyl cyanurate, triallyl isocyanurate, or acrylamide. The weight average molecular weight of the prepolymers can be 400 to 10,000 Daltons.

As used herein, the term “thermoplastic” refers to a material that is plastic or deformable, melts to a liquid when heated, and freezes to a brittle, glassy state when cooled sufficiently. Examples of thermoplastic polymers that can be used include cyclic olefin polymers (including polynorbornenes and copolymers containing norbornenyl units, for example copolymers of a cyclic polymer such as norbornene and an acyclic olefin such as ethylene or propylene), fluoropolymers (e.g., polyvinyl fluoride (PVF), polyvinylidene fluoride (PVDF), fluorinated ethylene-propylene (FEP), polytetrafluoroethylene (PTFE), poly(ethylene-tetrafluoroethylene (PETFE), perfluoroalkoxy (PFA)), polyacetals (e.g., polyoxyethylene and polyoxymethylene), poly(C₁₋₆ alkyl)acrylates, polyacrylamides (including unsubstituted and mono-N— and di-N—(C₁₋₈ alkyl)acrylamides), polyacrylonitriles, polyamides (e.g., aliphatic polyamides, polyphthalamides, and polyaramides), polyamideimides, polyanhydrides, polyarylene ethers (e.g., polyphenylene ethers), polyarylene ether ketones (e.g., polyether ether ketones (PEEK) and polyether ketone ketones (PEKK), polyarylene ketones, polyarylene sulfides (e.g., polyphenylene sulfides (PPS)), polyarylene sulfones (e.g., polyethersulfones (PES), polyphenylene sulfones (PPS), and the like), polybenzothiazoles, polybenzoxazoles, polybenzimidazoles, polycarbonates (including homopolycarbonates and polycarbonate copolymers such as polycarbonate-siloxanes, polycarbonate-esters, and polycarbonate-ester-siloxanes), polyesters (e.g., polyethylene terephthalates, polybutylene terephthalates, polyarylates, and polyester copolymers such as polyester-ethers), polyetherimides (including copolymers such as polyetherimide-siloxane copolymers), polyimides (including copolymers such as polyimide-siloxane copolymers), poly(C₁₋₆ alkyl)methacrylates, polymethacrylamides (including unsubstituted and mono-N— and di-N—(C₁₋₈ alkyl)acrylamides), polyolefins (e.g., polyethylenes, such as high density polyethylene (HDPE), low density polyethylene (LDPE), and linear low density polyethylene (LLDPE), polypropylenes, and their halogenated derivatives (such as polytetrafluoroethylenes), and their copolymers, for example ethylene-alpha-olefin copolymers, polyoxadiazoles, polyoxymethylenes, polyphthalides, polysilazanes, polysiloxanes (silicones), polystyrenes (including copolymers such as acrylonitrile-butadiene-styrene (ABS) and methyl methacrylate-butadiene-styrene (MBS)), polysulfides, polysulfonamides, polysulfonates, polysulfones, polythioesters, polytriazines, polyureas, polyurethanes, vinyl polymers (including polyvinyl alcohols, polyvinyl esters, polyvinyl ethers, polyvinyl halides (e.g., polyvinyl fluoride), polyvinyl ketones, polyvinyl nitriles, polyvinyl thioethers, and polyvinylidene fluorides), or the like. A combination comprising at least one of the foregoing thermoplastic polymers can be used.

The expanded hexagonal boron nitride can be contained in the composite in an amount sufficient to provide the composite suitable thermal conductivity, dielectric constant, and mechanical properties. The expanded hexagonal boron nitride can be present in the composite in an amount of 1 to 90 wt %, or 1 to 85 wt %, or 5 to 80 wt %, or 1 to 20 wt % based on a total weight of the composite. The composite can have a thermal conductivity of 1 W/m·K or more, or of 2 W/m·K or more, or 4 W/m·K or more, or 1 to 50 W/m·K measured according to ASTM D5470-12. The composite can have a dielectric constant of 1.5 to 15, or 3 to 12, or 4 to 10, measured, for example, at room temperature at 5.75×10⁹ Hz. The composite can have a coefficient of thermal expansion of 1 to 50 parts per million per degree Celsius (ppm/° C.), or 2 to 40 ppm/° C., or 4 to 30 ppm/° C.

The composite can further comprise an additional filler, for example, a filler to adjust the dielectric properties of the composite. A low coefficient of expansion filler, for example, glass beads, silica, or ground micro-glass fibers, can be used. A thermally stable fiber, for example, an aromatic polyamide, or a polyacrylonitrile, can be used. Representative fillers include titanium dioxide (rutile and anatase), barium titanate (BaTiO₃), Ba₂Ti₉O₂₀, strontium titanate, fused amorphous silica, corundum, wollastonite, aramide fibers (for example KEVLAR™ from DuPont), fiberglass, quartz, aluminum nitride, silicon carbide, beryllia, alumina, magnesia, mica, talcs, nanoclays, aluminosilicates (natural and synthetic), and fumed silicon dioxide (for example Cab-O-Sil, available from Cabot Corporation), each of which can be used alone or in combination.

The expanded hexagonal boron nitride can be used in thermal management applications, for example, in a thermal management assembly. The thermal management assembly can comprise the composite material, wherein the composite material is in contact with at least one external heat transfer surface to conduct heat away from the at least one external heat transfer surface. The composite material can be disposed between an external surface of a heat-generating member and an external surface of a heat-dissipative member to provide a thermally conductive transfer there between. The heat-generating member can be an electronic component or circuit board, and the heat dissipative member can be a heat sink or circuit board.

An article can comprise the expanded hexagonal boron nitride. The article can be for use in a sewage treatment application, a military application, or an aviation application.

In an embodiment, the present method is a method for preparing expanded hexagonal boron nitride by a carbothermal reduction and nitridation reaction, in particular a process for preparing expanded hexagonal boron nitride in a one-step reaction using a template method, in the field of inorganic non-metallic powder materials. The method can comprise: (1) a boron compound, carbon template and an organic solvent are mixed in a given ratio and stirred, then dried by evaporation to obtain a mixture of a boron compound and expanded graphite or expandable graphite; (2) the mixture obtained in (1) is put into a graphite crucible, and undergoes a nitriding reaction by carbothermal reduction in flowing nitrogen for 1 to 10 hours; and (3) surplus carbon is removed from the product obtained in (2), to finally obtain pure expanded hexagonal boron nitride with a specific surface area of 20 to 100 m²/g and an expanded specific volume of 30 to 200 mL/g, or 100 to 200 mL/g.

An innovative feature of the present disclosure is that expanded graphite can be used as a template and a reactant, and a carbothermal reduction and nitridation reaction can be used, with the assistance of a suitable dispersant and a rational heating process, to prepare pure expanded hexagonal boron nitride efficiently in one reaction step. The use of a suitable dispersant can ensure high solubility of the boron compound and maintain good dispersion of graphite, thereby enabling the boron compound and graphite to mix uniformly, while maintaining good infiltration therebetween. A carbon template can be used as a starting material; not only can this serve as a carbon source for the carbothermal reduction and nitridation reaction, but the carbon template can also be used as a template for an in-situ nitriding reaction by carbothermal reduction to produce hexagonal boron nitride.

The present method is a simple and efficient process, using inexpensive starting materials. The expanded hexagonal boron nitride prepared can be puffy and porous, having a large specific surface area. The use of an organic solvent as a dispersant during the mixing can not only ensure uniform mixing of the boron compound with the carbon template, but the organic solvent can be removed by heating in a low-temperature oven, thereby eliminating the need for complex downstream processes for the isolation and removal of impurities used in other preparation methods.

The present method can use an excess of carbon template in order to ensure that there is no residual boron compound in the crude product, and surplus carbon template can be removed completely by a simple one-step process for removing carbon by heating, to produce hexagonal boron nitride of high purity.

The present method can use a suitable heating system during the carbothermal reduction and nitridation reaction, thereby ensuring that the boron compound can react directly and completely with the carbon template and the nitrogen, so that the product conversion rate is high.

The starting materials employed, for example, the carbon template, the boron compound, and organic solvent, are all readily available and inexpensive, so the cost of industrial production can be reduced, facilitating mass industrial production of pure expanded boron nitride.

The expanded boron nitride produced by the present method can be loose, and the sheets thereof can be easily peeled apart, so a shortcut can be provided for subsequent research into the efficient production of large-sized sheets of two-dimensional hexagonal boron nitride.

The following examples are provided to illustrate articles with enhanced thermal capability. The examples are merely illustrative and are not intended to limit devices made in accordance with the disclosure to the materials, conditions, or process parameters set forth therein. Obviously, the examples described are merely some, not all, of the examples of the present disclosure. All other examples obtained by those skilled in the art on the basis of the examples in the present disclosure, without making any inventive effort, are included in the scope of protection of the present disclosure. The following examples, and features therein, may be combined with each other where no conflict arises.

### EXAMPLES

In the examples, an X-ray diffractometer was used to analyze the expanded hexagonal boron nitride, and a scanning electron microscope is used to observe the morphology of the expanded hexagonal boron nitride.

### Example 1: Preparation of an Expanded Hexagonal Boron Nitride

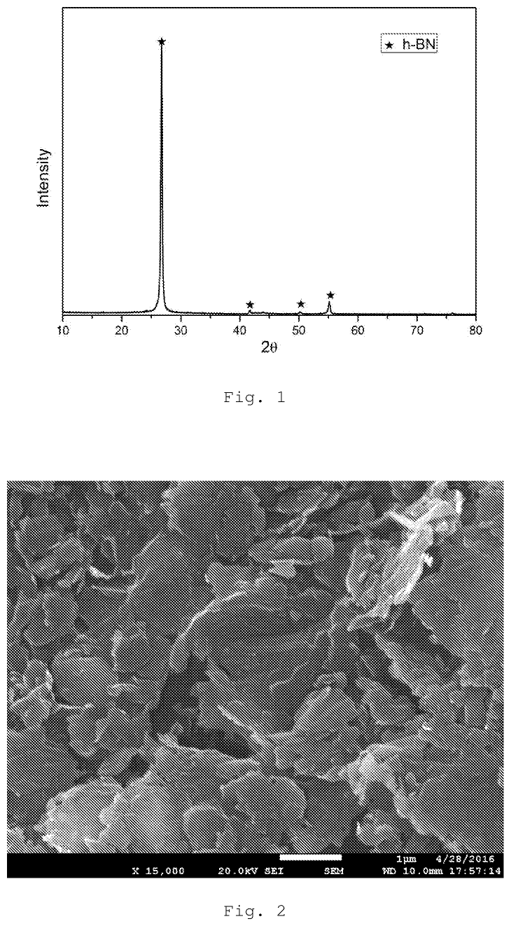

A mixture was formed by dissolving 5 g of boric acid in 75 mL of ethanol and then adding 1 g of expanded graphite. The mixture was stirred using a magnetic stir bar for 8 hours. After stirring, the stirred viscous liquid mixture was put in an oven at 90° C. to dry, to obtain a dried mixture of the boron compound and the expanded graphite. The dried mixture was then spread flat in a graphite crucible, and put into a tubular furnace. At an N₂ flow rate of 100 mL/min, the tubular furnace was heated to a first temperature of 400° C. at the rate of 10° C./min and held at this first temperature for 2 hours, then heated to a second temperature of 800° C. at a rate of 10° C./min and held at this second temperature for 2 hours, then heated to a third temperature of 1,400° C. at a rate of 5° C./min and held at this third temperature for 2.5 hours, and finally cooled to room temperature. Once the reaction was complete, the crude product obtained was put into a muffle furnace and held at a temperature of 620° C. for 5 hours to remove surplus carbon and to finally obtain an expanded hexagonal boron nitride in the form of a white powder with a specific surface area of 73 m²/g and an expanded specific volume of 148 mL/g. The X-ray diffraction spectrum for the expanded hexagonal boron nitride is illustrated in FIG. 1. An SEM image of is shown in FIG. 2.

### Example 2: Preparation of an Expanded Hexagonal Boron Nitride

A mixture was formed by dissolving 9 g of boric acid in 75 mL of ethanol and then adding 1 g of expanded graphite. The mixture was stirred using a magnetic stir bar for 8 hours. After stirring, the stirred viscous liquid mixture is put into an oven at 90° C. to dry, to obtain a dried mixture of the boron compound and the expanded graphite. The dried mixture was then spread flat in a graphite crucible, and put into a tubular furnace. At an N₂ flow rate of 100 mL/min, the tubular furnace was heated to a first temperature of 400° C. at the rate of 10° C./min and held at this first temperature for 2 hours, then heated to a second temperature of 800° C. at a rate of 10° C./min and held at this second temperature for 2 hours, then heated to a third temperature of 1,400° C. at a rate of 5° C./min and held at this third temperature for 2.5 hours, and finally cooled to room temperature. Once the reaction was complete, the crude product obtained was put into a muffle furnace and held at a temperature of 620° C. for 5 hours to remove surplus carbon and to finally obtain an expanded hexagonal boron nitride in the form of a white powder with a specific surface area of 30 m²/g and an expanded specific volume of 94 mL/g.

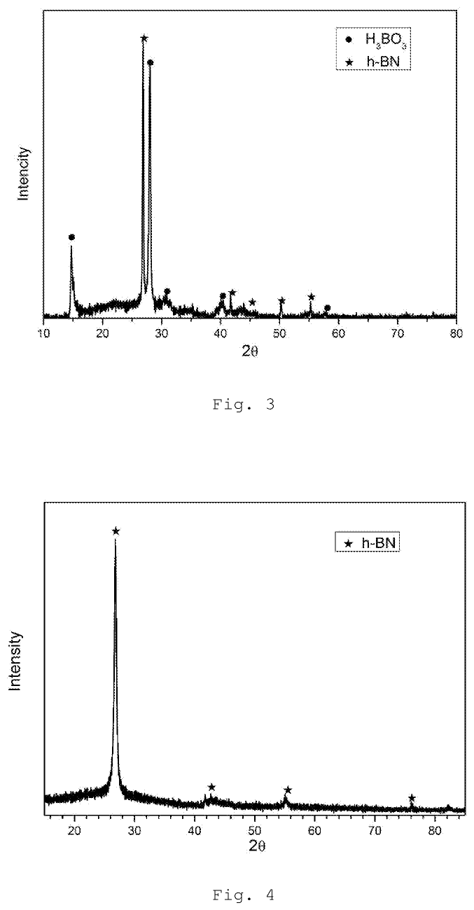

The X-ray diffraction spectrum for the expanded hexagonal boron nitride is illustrated in FIG. 3.

### Example 3: Use of a Single Heating Step During the Reaction

A mixture was formed by dissolving 5 g of boron oxide in 75 mL of methanol and then adding 1 g of expanded graphite. The mixture was stirred using a magnetic stir bar for 1 hours. After stirring, the stirred viscous liquid mixture was put into an oven at 90° C. to dry, to obtain a dried mixture of the boron compound and the expanded graphite. The dried mixture was then spread flat in a graphite crucible, and put into a tubular furnace. At an N₂ flow rate of 100 mL/min, the tubular furnace was heated to a temperature of 1,400° C. at the rate of 5° C./min and held at this temperature for 2.5 hours, then cooled to room temperature. Once the reaction is complete, the crude product obtained is put into a muffle furnace and held at a temperature of 750° C. for 5 hours to remove surplus carbon, but no expanded white powder is finally obtained.

### Example 4: Effect of a Reduced Stirring Time During the Mixing

A mixture was formed by dissolving 5 g of boron oxide in 75 mL of methanol and then adding 1 g of expanded graphite. The mixture was stirred using a magnetic stir bar for 1 hour. After stirring, the stirred viscous liquid mixture was put in an oven at 90° C. to dry, to obtain a dried mixture of the boron compound and the expanded graphite. The dried mixture was then spread flat in a graphite crucible, and put into a tubular furnace. At an N₂ flow rate of 100 mL/min, the tubular furnace was heated to a first temperature of 400° C. at the rate of 10° C./min and held at this first temperature for 1 hour, then heated to a second temperature of 800° C. at a rate of 5° C./min and held at this temperature for 2 hours, then heated to a third temperature of 1,400° C. at a rate of 5° C./min and held at this third temperature for 2.5 hours, and finally then cooled to room temperature. Once the reaction was complete, the crude product obtained was put into a muffle furnace and held at a temperature of 750° C. for 5 hours to remove surplus carbon and to finally obtain an expanded hexagonal boron nitride in the form of a white powder with a specific surface area of 81 m²/g and an expanded specific volume of 193 mL/g.

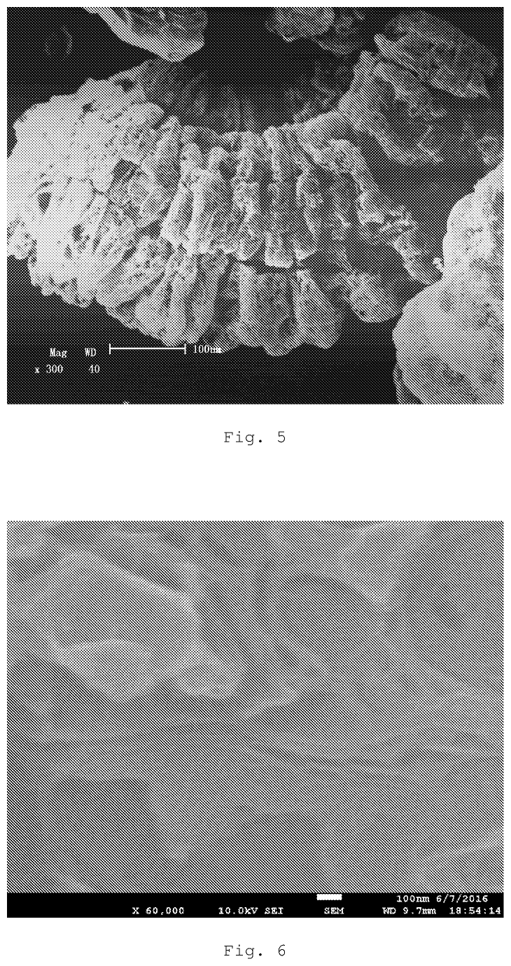

The X-ray diffraction spectrum for the expanded hexagonal boron nitride is illustrated in FIG. 4. SEM images are shown in FIG. 5 and FIG. 6.

### Results

The XRD results of Example 1 in FIG. 1 show that expanded hexagonal boron nitride is formed and that there is surprisingly no residual boric acid present in the expanded hexagonal boron nitride. Without being bound by theory, it is assumed that this result is likely due to the expanded graphite being present in excess in the carbothermal reduction and nitridation reaction. FIG. 1 further shows that the expanded hexagonal boron nitride is also free of residual expanded graphite, showing that complete removal of the expanded graphite is possible. In other words, with a slight excess of expanded graphite, the resultant expanded hexagonal boron nitride can be free of both residual boron compound and residual expanded graphite as the complete removal of the expanded graphite is possible by means of a one-step carbon removal process.

The XRD results of Example 2 in FIG. 3 also show that expanded hexagonal boron nitride is formed, but also show that there is a certain amount of residual boric acid present in the expanded hexagonal boron nitride. Without being bound by theory, it is assumed that this result is likely due to the boric acid being present in excess in the carbothermal reduction and nitridation reaction. While residual boron compound can be removed by subsequent processing, such as centrifugation, these processes are complex and it is difficult to remove all of the residual boron compound.

Comparing Example 2 with Example 1, it can be seen that the specific surface area and the expanded specific volume can be increased by increasing the initial amount of the boron compound relative to the expanded graphite. These increased values are likely due to the presence of residual boron compound in the expanded hexagonal boron nitride.

It can be seen by comparing Examples 3 and 4 that the method of heating during the carbothermal reduction and nitridation reaction can determine whether or not expanded hexagonal boron nitride is formed. For example, Example 3 shows that when the heating method does not include multiple heating stages, the expanded hexagonal boron nitride is not formed, illustrating that heating in stages can play an important role in the production of expanded hexagonal boron nitride. In contrast, using the same amounts of boron oxide and expanded graphite, the XRD results for Example 4 in FIG. 4 show that pure hexagonal boron nitride was produced.

FIG. 5 and FIG. 6 are SEM images of the expanded hexagonal boron nitride of Example 4 taken at different magnifications. It can be seen from FIG. 5, that when the heating occurs in stages, the original appearance of the expanded carbon template is reproduced in the expanded hexagonal boron nitride. It can be seen from FIG. 6 that a wedged-cavity-type intersection is present between microscopic sheets. This intersection type can have a positive effect in terms of improving the longitudinal thermal conductivity of a composite material comprising the expanded hexagonal boron nitride.

In comparing the morphology of the expanded hexagonal boron nitride formed in Example 1 and Example 4, in FIG. 2 and FIG. 5, respectively, it can be seen that the expanded hexagonal boron nitride of Example 1 is present in the form of nanosheets whereas the expanded hexagonal boron nitride of Example 4 is particulate. Without being bound by theory, it is believed that the different morphologies is due to the different stirring time of the mixtures. It is believed that the increased period of magnetic stirring in Example 1 caused the expanded graphite to break up into isolated sheets, such that the resultant expanded hexagonal boron nitride reproduced is distributed in sheets, and the swelling effect is not noticeable. Conversely, the short period of magnetic stirring of Example 4 of only 1 hour was not enough to break up the expanded graphite particles and the resultant expanded hexagonal boron nitride templated off of the expanded graphite particles took on the particulate morphology.

Set forth below are non-limiting embodiments of the present disclosure.

Embodiment 1: A method for preparing expanded hexagonal boron nitride, comprising: mixing a boron compound and a carbon template in an organic solvent; removing the organic solvent to provide a dried mixture of the boron compound and the carbon template; exposing the dried mixture to a nitrogen-containing gas under conditions effective to provide a crude product comprising hexagonal boron nitride; removing the carbon template from the crude product to provide the expanded hexagonal boron nitride.

Embodiment 2: The method of any one or more of the preceding embodiments, wherein the boron compound comprises an amine pentaborate, a boric ester, borax, boric acid or a salt thereof, pyroboric acid or a salt thereof, tetraboric acid or a salt thereof, boron oxide, or a combination comprising one or more of the foregoing.

Embodiment 3: The method of any one or more of the preceding embodiments, wherein the carbon template comprises a surface treated carbon template comprising a plurality of one or both of hydroxyl and carboxyl functional groups.

Embodiment 4: The method of any one or more of the preceding embodiments, wherein the organic solvent comprises ethanol, methanol, glycerin, a polyether, polypropanol, or a combination comprising one or more of the foregoing.

Embodiment 5: The method of any one or more of the preceding embodiments, wherein the mixing occurs at a temperature of 0 to 60° C.

Embodiment 6: The method of any one or more of the preceding embodiments, wherein the mixing occurs for 0.5 to 10 hours.

Embodiment 7: The method of any one or more of the preceding embodiments, wherein the mixing comprises at least one of mixing for greater than or equal to 2 hours, ultrasonically vibrating during mixing, and wet ball mixing.

Embodiment 8: The method of any one or more of the preceding embodiments, wherein the mixture comprises 5 to 200 mL, or 5 to 25 mL, or 5 to 15 mL, or 25 to 200 mL of the organic solvent per 1 g of the total of the boron compound and the carbon template.

Embodiment 9: The method of any one or more of the preceding embodiments, wherein the removing the organic solvent comprises heating the mixture, applying a vacuum pressure to the mixture, freeze-drying the mixture, or a combination of one or more of the foregoing.

Embodiment 10: The method of any one or more of the preceding embodiments, wherein the dry mixture comprises less than or equal to 1 mL, or 0 to 0.1 mL of the organic solvent per 1 g of the total of the boron compound and the carbon template.

Embodiment 11: The method of any one or more of the preceding embodiments, wherein the molar ratio of carbon template to boron compound in the mixture is 1:0.2 to 1:2.

Embodiment 12: The method of any one or more of the preceding embodiments, further comprising spreading the dried mixture in a graphite crucible prior to the exposing.

Embodiment 13: The method of any one or more of the preceding embodiments, wherein the exposing occurs for 1 to 10 hours.

Embodiment 14: The method of any one or more of the preceding embodiments, wherein the exposing comprises flowing nitrogen gas at a flow rate of 40 to 1,000 mL/min, or 60 to 200 mL/min.

Embodiment 15: The method of any one or more of the preceding embodiments, wherein the exposing comprises: heating the dry mixture to a first temperature of 100 to 500° C. at a rate of 3 to 10° C./min; maintaining the first temperature for 0.5 to 3 hours; heating to a second temperature of 700 to 1,100° C. at a rate of 3 to 10° C./min; maintaining the second temperature for 0.5 to 3 hours; heating to a third temperature of 1,200 to 1,700° C. at a rate of 3 to 10° C./min; and maintaining the third temperature for 0.5 to 3 hours.

Embodiment 16: The method of any one or more of the preceding embodiments, wherein the removing the carbon template from the crude product to provide the expanded hexagonal boron nitride comprises heating in the presence of oxygen.

Embodiment 17: The method of any one or more of the preceding embodiments, further comprising mixing the expanded hexagonal boron nitride with a polymer to form a polymer composite material.

Embodiment 18: An expanded hexagonal boron nitride prepared by any one or more of the foregoing embodiments.

Embodiment 19: An expanded hexagonal boron nitride having a specific surface area of 20 to 100 m²/g that can be prepared by any one or more of the foregoing embodiments.

Embodiment 20: An expanded hexagonal boron nitride having an expanded volume of 100 to 200 mL/g that can be prepared by any one or more of the foregoing embodiments.

Embodiment 21: A composite material comprising, a polymer matrix; and the expanded hexagonal boron nitride of any one or more of the preceding embodiments dispersed in the polymer matrix.

Embodiment 22: The composite material of Embodiment 21, wherein the composite material has a first and a second heat transfer surface.

Embodiment 23: The composite material of any one or more of embodiments 21 to 22, comprising 1 to 90 weight percent, or 5 to 80 weight percent, or 1 to 20 weight percent of the expanded boron nitride filler, based on the total weight of the composite material.

Embodiment 24: The composite material of any one or more of embodiments 21 to 23, wherein the composite material has an average thickness of 0.1 to 25 millimeters.

Embodiment 25: The composite material of any one or more of embodiments 21 to 24, wherein the polymer matrix comprises polyurethane, silicone, polyolefin, polyester, polyamide, fluorinated polymer, polyalkylene oxide, polyvinyl alcohol, ionomer, cellulose acetate, polystyrene, or a combination comprising at least one of the foregoing.

Embodiment 26: The composite material of any one or more of embodiments 21 to 25, wherein the polymer matrix is a compressible foam.

Embodiment 27: A thermal management assembly comprising the composite material of one or more of Embodiments 21 to 26, wherein the composite material is in contact with at least one external heat transfer surface to conduct heat away from the at least one external heat transfer surface.

Embodiment 28: The thermal management assembly of Embodiment 27, wherein the composite material is disposed between an external surface of a heat-generating member and an external surface of a heat-dissipative member to provide a thermally conductive transfer there between.

Embodiment 29: The thermal management assembly of Embodiment 28, wherein the heat-generating member is an electronic component or circuit board, and the heat dissipative member is a heat sink or circuit board.

Embodiment 30: An article comprising the expanded hexagonal boron nitride of any one or more of the preceding embodiments.

Embodiment 31: The article of Embodiment 30, wherein the article is for use in a sewage treatment application, a military application, or an aviation application.

Embodiment 32: The method of any one or more of the foregoing, wherein the mixing is conducted in the presence of a dispersant, preferably an anionic surfactant, more preferably sodium dodecyl sulfate.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

The terms “a” and “an” do not denote a limitation of quantity, but rather denote the presence of at least one of the referenced item. The term “or” means “and/or” unless clearly indicated otherwise by context. Reference throughout the specification to “an embodiment”, “another embodiment”, “some embodiments”, and so forth, means that a particular element (e.g., feature, structure, step, or characteristic) described in connection with the embodiment is included in at least one embodiment described herein, and may or may not be present in other embodiments. In addition, it is to be understood that the described elements may be combined in any suitable manner in the various embodiments.

In general, the compositions, methods, and articles can alternatively comprise, consist of, or consist essentially of, any ingredients, steps, or components herein disclosed. The compositions, methods, and articles can additionally, or alternatively, be formulated, conducted, or manufactured so as to be devoid, or substantially free, of any ingredients, steps, or components not necessary to the achievement of the function or objectives of the present claims.

Unless specified to the contrary herein, all test standards are the most recent standard in effect as of the filing date of this application, or, if priority is claimed, the filing date of the earliest priority application in which the test standard appears.

The endpoints of all ranges directed to the same component or property are inclusive of the endpoints, are independently combinable, and include all intermediate points and ranges. For example, ranges of “up to 25 wt %, or 5 to 20 wt %” is inclusive of the endpoints and all intermediate values of the ranges of “5 to 25 wt %,” such as 10 to 23 wt %, etc.

The term “combination” is inclusive of blends, mixtures, alloys, reaction products, and the like. Also, “combinations comprising at least one of the foregoing” means that the list is inclusive of each element individually, as well as combinations of two or more elements of the list, and combinations of at least one element of the list with like elements not named.

Unless defined otherwise, technical and scientific terms used herein have the same meaning as is commonly understood by one of skill in the art to which this disclosure belongs.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

1. A method for preparing expanded hexagonal boron nitride, the method comprising:
mixing a boron compound and a carbon template in an organic solvent;
removing the organic solvent to provide a dried mixture of the boron compound and the carbon template;
exposing the dried mixture to a nitrogen-containing gas under conditions effective to provide a crude product comprising hexagonal boron nitride;
removing the carbon template from the crude product to provide the expanded hexagonal boron nitride.

2. The method of any claim 1, wherein the boron compound comprises an amine pentaborate, a boric ester, borax, boric acid or a salt thereof, pyroboric acid or a salt thereof, tetraboric acid or a salt thereof, boron oxide, or a combination comprising one or more of the foregoing.

3. The method of claim 1, wherein the carbon template comprises a surface treated carbon template comprising a plurality of one or both of hydroxyl and carboxyl functional groups.

4. The method of claim 1, wherein the organic solvent comprises ethanol, methanol, glycerin, a polyether, or a combination comprising one or more of the foregoing.

5. (canceled)

6. (canceled)

7. (canceled)

8. The method of claim 1, wherein the mixture comprises 5 to 200 mL of the organic solvent per 1 g of the total of the boron compound and the carbon template.

9. (canceled)

10. The method of claim 1, wherein the dry mixture comprises less than or equal to 1 mL the organic solvent per 1 g of the total of the boron compound and the carbon template.

11. The method of claim 1, wherein the molar ratio of carbon template to boron compound in the mixture is 1:0.2 to 1:2.

12. The method of claim 1, further comprising spreading the dried mixture in a graphite crucible prior to the exposing.

13. (canceled)

14. The method of claim 1, wherein the exposing comprises flowing nitrogen gas at a flow rate of 40 to 1,000 mL/min.

15. The method of claim 1, wherein the exposing comprises:
heating the dry mixture to a first temperature of 100 to 500° C. at a rate of 3 to 10° C./min;
maintaining the first temperature for 0.5 to 3 hours;
heating to a second temperature of 700 to 1,100° C. at a rate of 3 to 10° C./min;
maintaining the second temperature for 0.5 to 3 hours;
heating to a third temperature of 1,200 to 1,700° C. at a rate of 3 to 10° C./min; and
maintaining the third temperature for 0.5 to 3 hours.

16. The method of claim 1, wherein the removing the carbon template from the crude product to provide the expanded hexagonal boron nitride comprises heating in the presence of oxygen.

17. The method of claim 1, further comprising mixing the expanded hexagonal boron nitride with a polymer to form a polymer composite material.

18. An expanded hexagonal boron nitride wherein the expanded hexagonal boron nitride has at least one of a specific surface area of 20 to 100 m²/g or an expanded volume of 100 to 200 mL/g.

19. (canceled)

20. (canceled)

21. A composite material comprising:
a polymer matrix; and
the expanded hexagonal boron nitride of claim 18 dispersed in the polymer matrix.

22. (canceled)

23. The composite material of claim 21, comprising 1 to 90 weight percent of the expanded hexagonal boron nitride, based on the total weight of the composite material.

24. The composite material of claim 21, wherein the composite material has an average thickness of 0.1 to 25 millimeters.

25. The composite material of claim 21, wherein the polymer matrix comprises a polyurethane, a silicone polymer, a polyolefin, a polyester, a polyamide, a fluorinated polymer, a polyalkylene oxide, polyvinyl alcohol, an ionomer, cellulose acetate, a polystyrene, or a combination comprising at least one of the foregoing.

26. The composite material of claim 21, wherein the polymer matrix is a compressible foam.

27. A thermal management assembly comprising the composite material of claim 21, wherein the composite material is in contact with at least one external heat transfer surface to conduct heat away from the at least one external heat transfer surface.

28. (canceled)

29. (canceled)

30. An article comprising the expanded hexagonal boron nitride of claim 18.

31. (canceled)
